(19) United States
(12) Patent Application Publication
(10) Pub. No.: US 2010/0156248 A1
(43) Pub. Date: Jun. 24, 2010

(54) PACKAGE STRUCTURE AND METHOD FOR A PIEZOELECTRIC TRANSFORMER

(75) Inventors: Jinlong Du, Beijing (CN); Bin Wu, Beijing (CN)

Correspondence Address: WOLF GREENFIELD & SACKS, P.C., 600 ATLANTIC AVENUE, BOSTON, MA, 02210-2206, US

(73) Assignee: China Electronics Weihua Co., LTD., Beijing (CN)

(21) Appl. No.: 12/342,525

(22) Filed: Dec. 23, 2008

(51) Int. Cl. H01L 41/053

(52) U.S. Cl. 310/352

(57) ABSTRACT

The disclosed is package structure for a piezoelectric transformer, which comprises: a shell for supporting the piezoelectric transformer at its node plane; a plurality of electrical connection frames which are fixed on the shell for connecting with electrodes of the piezoelectric transformer and conducting heat from piezoelectric transformer by connection points arranging along the electrical connection frame; and a plurality of connection pins deposited on the electrical connection frames for connecting to the outside circuit. Further, the shell has a wedge structure part which fixes the piezoelectric transformer at its node plane. Correspondingly, a package method for a piezoelectric transformer is also disclosed. Thus, the structure and package method allow a piezoelectric transformer to vibrate freely and have good heat management.

### TECHNICAL FIELD OF THE INVENTION

The present invention generally relates to the field of the piezoelectric transformer, and more particularly to package structure and method for a piezoelectric transformer.

### BACKGROUND OF THE INVENTION

A piezoelectric transformer (PT) converts electric energy into ultrasonic vibration by converse piezoelectric effect at the input part, and the ultrasonic vibration into electric energy with a different voltage by piezoelectric effect at the output part. Compared with a conventional Electromagnetic transformer, a piezoelectric transformer has many advantages such as high-power density, high efficiency, low profile, small size, light weight, no windings, electromagnetic noise-free operation, and no inflammability. More, the shear mode piezoelectric transformer is potential piezoelectric transformer that the power density and output power are superior to other piezoelectric transformer for its large K15 (electromechanical coupling coefficient) and Qm (mechanical quality factor) value. Today, the maximum output power for shear mode piezoelectric transformer has been beyond 170 W that is attractive to the power supply and ballast applications.

Although the attractive character of the piezoelectric transformer can perform, the structure and package method is another important aspect. The standards to judge the structure and package are the structure support to the piezoelectric transformer, the electrical connection with the piezoelectric transformer and the thermal management.

Because of the principle of the piezoelectric transformer, the free vibration must be supported and impediment to the vibration will decrease the efficiency of the piezoelectric transformer extremely. One of the ways is that we find the node points or node plane to fix the piezoelectric transformer. For the shear vibration mode piezoelectric transformer, the node plane is in the middle along the X axis, as shown in FIG. 1.

In addition, the contact resistance between the electrical connection point and the piezoelectric transformer electrode is one of the resources to generate heat, and rational connection structure will decrease the contact resistance and the heat effectively. FIG. 2 shows a structure of a shear vibration mode piezoelectric transformer of an embodiment including the input electrode, output electrode and the control electrode, which described in U.S. patent “A Piezoelectric Phase Shifter” to DOU Jinlong et al., the disclosure of which is incorporated by reference herein. Although the piezoelectric transformer has high efficiency, dissipation of the heat is also needed. Heat generation and temperature rise of the piezoelectric transformer will decrease the efficiency of the piezoelectric transformer and involve into a vicious circle. The common criterion to judge the power handle capacity is the temperature rise below 20□. The structure and package for a piezoelectric transformer must be in favorite of the heat conduction.

Therefore, it is required to provide a structure and package method for piezoelectric transformer to vibrate freely, have small contact resistance and good heat conduction.

### SUMMARY OF THE INVENTION

Accordingly, the present invention provides a package structure for a piezoelectric transformer which includes: a shell for supporting the piezoelectric transformer at its node plane; a plurality of electrical connection frames for connecting with the piezoelectric transformer and conducting heat from the piezoelectric transformer; and a plurality of connection pins deposited on the electrical connection frames for connecting to the outside circuit. The frames fix on the shell and connect with the electrodes of the piezoelectric transformer by connection points arranging along the frames. Further, the shell has a wedge structure part which fixes the piezoelectric transformer at its node plane.

Accordingly, the present invention provides a package method for a piezoelectric transformer includes: the piezoelectric transformer is placed in a shell and supported at its node plane; electrodes of the piezoelectric transformer are connected with electrical connection frames by connection points arranging along the electrical connection frames; connection pins for connecting to the outside circuit are deposited on the electrical connection frames; the electrical connection frames are fixed on the shell. Further, the shell has a wedge structure part and the piezoelectric transformer is fixed by the wedge structure part at node plane of the piezoelectric transformer.

As can be seen from the above, in the disclosure, the shell supporting the piezoelectric transformer at its node plane allows the piezoelectric transformer to vibrate freely, connection points with the electrode of the piezoelectric transformer decrease contact resistance, thus decrease the heat generation, and the electrical connection frames and connection points also conduct heat from the piezoelectric transformer effectively. So a piezoelectric transformer with the above package structure and method has high efficiency. Moreover, the present invention provides an easy interface with the outside circuit though the connection pins.

### BRIEF DESCRIPTION OF THE DRAWINGS

The above and other advantages of the present disclosure will become more apparent by describing the embodiments in detail with reference to the accompanying drawings, furthermore the drawings described herein are for illustration purposes only and are not intended to limit the scope of the present disclosure in any way, in which:

FIG. 1 schematically illustrates a shear vibration mode piezoelectric transformer, its node plane and electrodes.

FIG. 2 schematically illustrates a shear vibration mode piezoelectric transformer of an embodiment.

FIG. 3 is an outline of the package structure of an embodiment of the invention.

FIG. 4 is electrical connection frames and the electric connection points according to an embodiment of the invention.

FIG. 5 is a wedge structure part of the shell according to an embodiment of the invention.

FIG. 6 is a perspective schematic view showing the package structure according to an embodiment of the invention.

### DETAILED DESCRIPTION OF THE PREFERRED EMBODIMENTS

The following description is merely exemplary in nature and is not intended to limit the present disclosure, application, or uses.

The embodiments are further illustrated in detail in conjunction with the drawings to make embodiments of the technical solutions and the advantages more apparent.

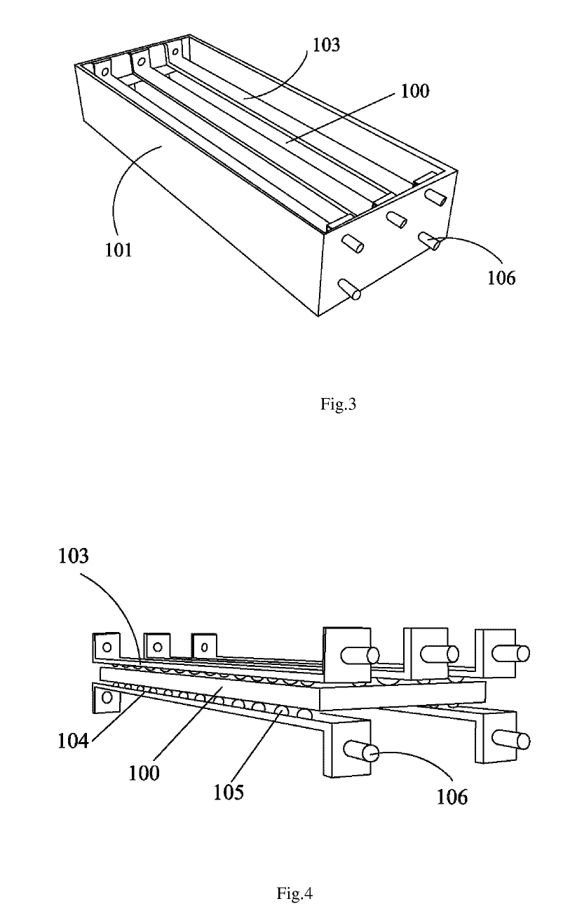

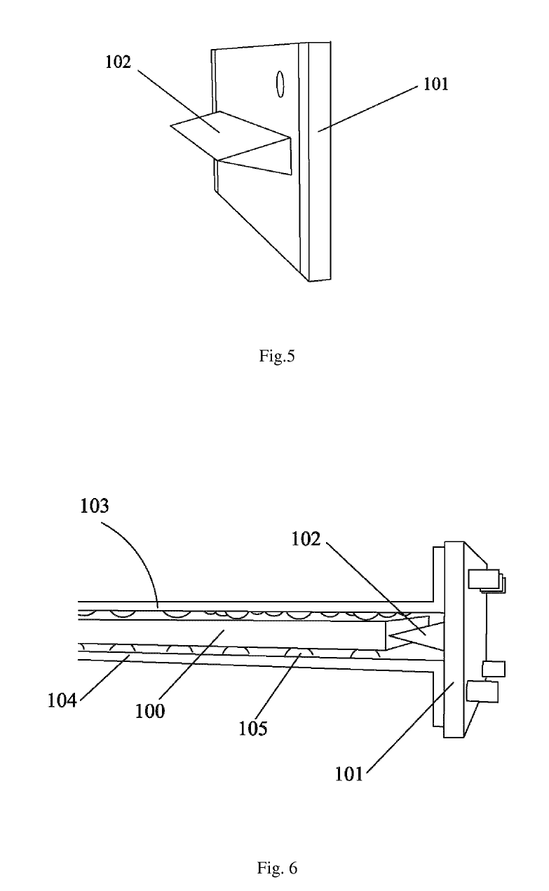

As shown in FIG. 3, FIG. 4 and FIG. 6, the outside shell 101 fixes the piezoelectric transformer (PT) 100 at its node plane, electrical connection frames 103, 104 connect with the electrodes of the piezoelectric transformer 100 and conduct thermal energy from the piezoelectric transformer 100, connection pins 106 are deposited on the electrical connection frames 103,104 for connecting to the outside circuit. As shown in FIG. 1, the node plane is on the middle of the X axis for the shear vibration mode piezoelectric transformer. The frames 103,104 fix on the shell and connect with the electrodes of piezoelectric transformer by connection points 105, as shown in the FIG. 4 and FIG. 5, along arranging the frames.

FIG. 5 is a wedge of the shell 101 according to a preferred embodiment of the invention. Further, as a preferred embodiment of the invention, the wedge structure part 102 of the shell 101 at all four sides supports the piezoelectric transformer 100 at the node plane of the piezoelectric transformer. With the wedge structure part 102, the contact area between the shell 101 and piezoelectric transformer 100 is minimized, thus the vibration hindrance of the piezoelectric transformer is decreased.

As shown in FIG. 3, in a preferred embodiment, the connection pins 106 for connecting to outside circuit pass through the shell 101 to fix. With this package structure and corresponding package method, it is easy and convenient to interface with the outside circuit, and the structure is more solid and easy manufactured.

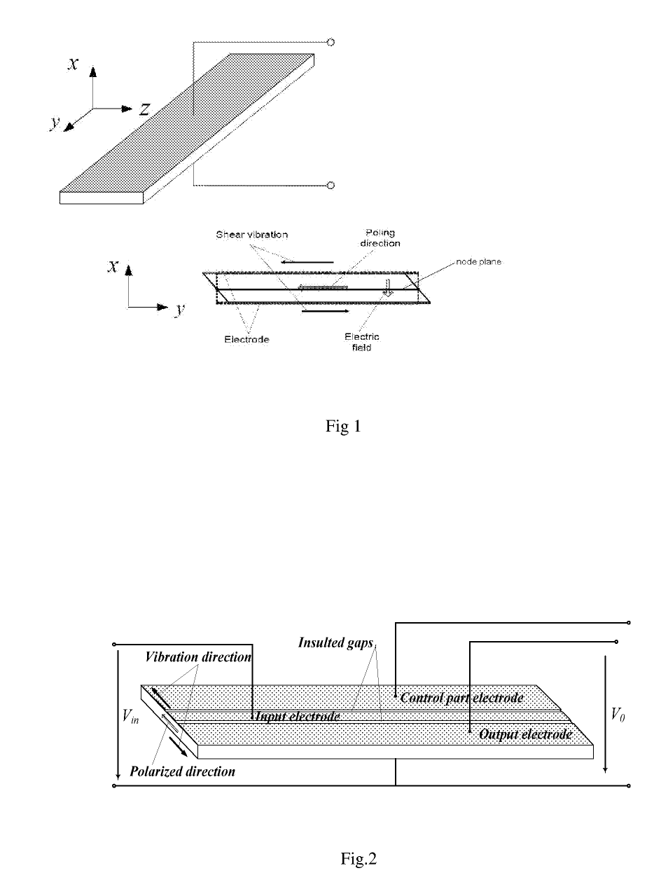

As shown in FIG. 3 and FIG. 4 and FIG. 6, in a preferred embodiment, the electrical connection frames includes top frames 103 and bottom frames 104, and connection points 105 on the top frames 103 are on underside surfaces of the top frames 103 and the connection points 105 on the bottom frames 104 are on upside surfaces of the bottom frames 104. The piezoelectric transformer (PT) 100 is places between the top frames 103 and bottom frames 104. Further, in an embodiment, there are three top frames 103 and two bottom frames 104. The three top frames connect with anodes of input electrode, output electrode and control electrode of a shear vibration mode piezoelectric transformer 100 respectively; one of the two bottom frames connects with cathodes of input electrode and output electrode of a shear vibration mode piezoelectric transformer 100, and another bottom frames connects with cathodes of control electrode of a shear vibration mode piezoelectric transformer 100. The FIG. 2 shows a shear vibration mode piezoelectric transformer and electrodes including input, output and control electrode. There are five connection pins 106 that are deposited on the three top frames 103 and the two bottom frames 104 respectively.

As shown in FIG. 4 and FIG. 6, in a preferred embodiment, the connection points 105 connecting the frames 103, 104 with the electrodes of the piezoelectric transformer 100 are half-ball in shape. With the half-ball shape, the contact area between the connect point 105 and electrode of the piezoelectric transformer 100 is minimized, thus impediment to the vibration of the piezoelectric transformer is decreased and the contact resistance between the connect point 105 and electrode of piezoelectric transformer is also smaller. Smaller contact resistance will generate less heat and provide higher efficiency for the piezoelectric transformer.

As shown in FIG. 3 and FIG. 5, the electrical connection points 105 arrange along the connection frame 103, 104. The distance between two neighboring points along the frame is small for decreasing the contact resistance. With the increasing of the contact area, the contact resistance decreases and the heat conduction increases, so the closer distance between two points will decrease the contact resistance and increase heat conduction, which will improve the properties of the piezoelectric transformer. In practice, the limitation of mold for the electrical connection frames and electrical connection points is also considered in determining the distance of two electrical connection points. In a preferred embodiment, the distance between two neighboring electrical connection points is 1 mm (millimeter).

In a preferred embodiment, the outside shell 101 and the wedge structure part 102 are made of the aluminum which is cheap to manufacture and have good heat conduction characteristic, but it is not limited.

In a preferred embodiment, the electrical connection frames 103, 104, the connection points 105 and the connection pins 106 are made of the copper which has good thermal and electric conductivity, but it is not limited.

The invention has been described in an illustrative manner, and it is to be understood that the terminology that has been used is intended to be in the nature of words of description rather than of limitation. Obviously, many modifications and variations of the present invention are possible in light of the above teachings. It is, therefore, to be understood that within the scope of the appended claims the invention may be practiced otherwise than as specifically described.

What is claimed is:

1. A package structure for a piezoelectric transformer, comprising:
a shell for supporting the piezoelectric transformer at its node plane;
a plurality of electrical connection frames which are fixed on the shell for connecting with electrodes of the piezoelectric transformer and conducting heat from piezoelectric transformer by connection points arranging along the electrical connection frame; and
a plurality of connection pins deposited on the electrical connection frames for connecting to the outside circuit.

2. The package structure according to claim 1, wherein the shell has a wedge structure part which fixes the piezoelectric transformer at its node plane.

3. The package structure according to claim 1, wherein the shell contacts around the node plane of the piezoelectric transformer to fix the piezoelectric transformer.

4. The package structure according to claim 2, wherein the wedge structure part contacts around the node plane of the piezoelectric transformer to fix the piezoelectric transformer.

5. The package structure according to claim 1, wherein the connection pins pass through the shell to fix.

6. The package structure according to claim 1, wherein the electrical connection frames includes top frames and bottom frames;
the piezoelectric transformer is placed between the top frames and bottom frames, and connects with the top frames and the bottom frames by the connect points.

7. The package structure according to claim 6, wherein there are three top frames which connect with anodes of input electrode, output electrode and control electrode of the piezoelectric transformer respectively;
there are two bottom frames, one of the bottom frames connects with cathodes of input electrode and output electrode of the piezoelectric transformer, and another bottom frame connects with cathodes of control electrode of the piezoelectric transformer;
there are five connection pins which are deposited on the top frames and the bottom frames respectively.

8. The package structure according to claim 1, wherein the connection points are half-ball shape.

9. The package structure according to claim 1, wherein the distance between the two neighboring connection points is 1 mm.

10. The package structure according to claim 2, wherein the shell and the wedge structure part are made of aluminum.

11. The package structure according to claim 1, wherein the electrical connection frames, connection points and connection pins are made of copper.

12. A package method for a piezoelectric transformer, comprising:
the piezoelectric transformer is placed in a shell and supported at its node plane;
electrodes of the piezoelectric transformer are connected with electrical connection frames by connection points arranging along the electrical connection frames; connection pins are deposited on the electrical connection frames for connecting to the outside circuit; and
the electrical connection frames are fixed on the shell.

13. The package method according to claim 12, wherein the piezoelectric transformer is fixed at its node plane by the wedge structure part of the shell.

14. The package method according to claim 12, wherein the shell contacts around the node plane of the piezoelectric transformer to fix the piezoelectric transformer.

15. The package method according to claim 13, wherein the wedge structure part contacts around the node plane of the piezoelectric transformer to fix the piezoelectric transformer.

16. The package method according to claim 12, further comprising:
the connection pin pass through the shell to fix.

17. The package method according to claim 12, wherein the electrical connection frames includes top frames and bottom frames;
the piezoelectric transformer is placed between the top frames and bottom frames, and connects with the top frames and the bottom frames by the connection points.

18. The package method according to claim 17, wherein there are three top frames and the three top frames are connected with anodes of input electrode, output electrode and control electrode of the piezoelectric transformer respectively;
there are two bottom frames, one of the bottom frames is connected with cathodes of input electrode and output electrode of the piezoelectric, and another bottom frames is connected with cathodes of control electrode of the piezoelectric transformer;
there are five connection pins and the five connection pins are deposited on the top frames and the bottom frames respectively.

19. The package method according to claim 12, wherein the connection points are half-ball shape.

20. The package method according to claim 12, wherein the distance between two neighboring connection points is 1 mm.

21. The package method according to claim 12, wherein the shell and the wedge structure part are made of aluminum.

22. The package method according to claim 12, wherein the electrical connection frames, connection points and connection pins are made of copper.
